(19) United States
(12) Patent Application Publication
(10) Pub. No.: US 2024/0037292 A1
(43) Pub. Date: Feb. 1, 2024

(54) KNOWLEDGE GRAPH FOR INTEROPERABILITY IN INDUSTRIAL METAVERSE FOR ENGINEERING AND DESIGN APPLICATIONS

(71) Applicant: Siemens Corporation, Washington, DC (US)

(72) Inventors: Georgia Olympia Brikis, Plainsboro, NJ (US); Tongtao Zhang, Lawrenceville, NJ (US); Utkarshani Jaimini, West Columbia, SC (US)

(73) Assignee: Siemens Corporation, Washington, DC (US)

(21) Appl. No.: 18/359,528

(22) Filed: Jul. 26, 2023

Related U.S. Application Data
(60) Provisional application No. 63/369,414, filed on Jul. 26, 2022.

(51) Int. Cl. G06F 30/17

(52) U.S. Cl. CPC G06F 30/17

(57) ABSTRACT

System and method enable development of an industrial metaverse used in engineering by computer aided design. A metaverse pipeline includes a plurality of metaverse entities including at least one design application and one simulation application configured to develop a virtual environment metaverse representation of an industrial facility. A metaverse knowledge graph describes semantics and relationships between the metaverse pipeline entities and is configured to exchange information across the software applications of the metaverse pipeline entities of various platforms while developing the virtual environment metaverse. The metaverse knowledge graph enables synchronization across metaverse development platforms, such that updates to one platform are transferrable, whereby the virtual entities and environment can be assimilated according to new edits.

### TECHNICAL FIELD

This application relates to virtual environment generation. More particularly, this application relates to development of an industrial metaverse with interoperability across various platforms via a specialized knowledge graph.

### BACKGROUND

The industrial metaverse is in its initial stages. The metaverse can be created with various platforms, including NX, AutoCAD, StarCCM+, Simcenter, Plant Simulation, Unity, Autodesk, and Nvidia omniverse, which has created a challenge of interoperability between these platforms. Currently, there is no developmental standard for the industrial metaverse. The information and data necessary to model the real world in a virtual environment is spread/scattered across multiple platforms. This leads to different platforms requiring different hardware and software. The different platforms often use different data models and terminologies to describe the same entity, making it difficult to connect data even if it has been aggregated in a single data file.

There is a need for modeling the semantics and relationships of the metaverse entities split across platforms, defining the semantics of the metaverse entities which can be transferred across platforms. There currently lacks any mechanism to enable real time interactivity across platforms where edits made on one platform can be communicated across platforms. Synchronization across platforms should not require re-running the entire development pipeline after the updates. There is a further need for reusability of virtual entities, and environment across the platforms where virtual entities and environments created for one platform can be seamlessly adapted for a new platform, domain, or scenario.

With the industrial metaverse in its early development stage, W3C along with companies working in metaverse domain have established a Metaverse standard forum (https://metaverse-standards.org/) for standardizing the metaverse development to address the problem of interoperability across metaverse platforms.

### SUMMARY

System and method enable development of an industrial metaverse used in engineering by computer aided design. A metaverse pipeline includes various metaverse entities (e.g., design application, simulation application) configured to develop a virtual environment metaverse representation of an industrial facility. A metaverse knowledge graph describes semantics and relationships between the metaverse pipeline entities and is configured to exchange information across the software applications of the metaverse pipeline entities of various platforms while developing the virtual environment metaverse. The disclosed system and method enables synchronization across metaverse development platforms, such that updates to one platform are transferrable, whereby the virtual entities and environment can be assimilated according to the new edits.

### BRIEF DESCRIPTION OF THE DRAWINGS

Non-limiting and non-exhaustive embodiments of the present disclosure are described with reference to the following FIGURES, wherein like reference numerals refer to like elements throughout the drawings unless otherwise specified.

FIG. 1 illustrates a framework example for virtual environment metaverse development using a metaverse knowledge graph in accordance with embodiments of this disclosure.

FIG. 2 illustrates a framework example of an example of a process for data exchanges for the metaverse knowledge graph in accordance with embodiments of this disclosure.

FIG. 3 illustrates an example of a computing environment within which embodiments of the disclosure may be implemented.

### DETAILED DESCRIPTION

Methods and systems are disclosed to address the issue of interoperability across industrial metaverse development platforms for engineering and design software tools or applications by applying a specialized knowledge graph when developing the virtual environment of an industrial metaverse. A knowledge graph is a set of triple or quads saved in the graph database, known as triple store. A knowledge graph captures the complexity of the real-world and stores information intuitively. Knowledge graphs are more flexible than traditional relational data models making it easy to add, edit and remove data to respond to real-world changes. Hence, this disclosure proposes a metaverse knowledge graph, a semantic network of metaverse meta-data entities and their relationships, enabling seamless representation of the physical world into the virtual metaverse platform. It functions as a connective platform between diverse systems, fusing data across different applications.

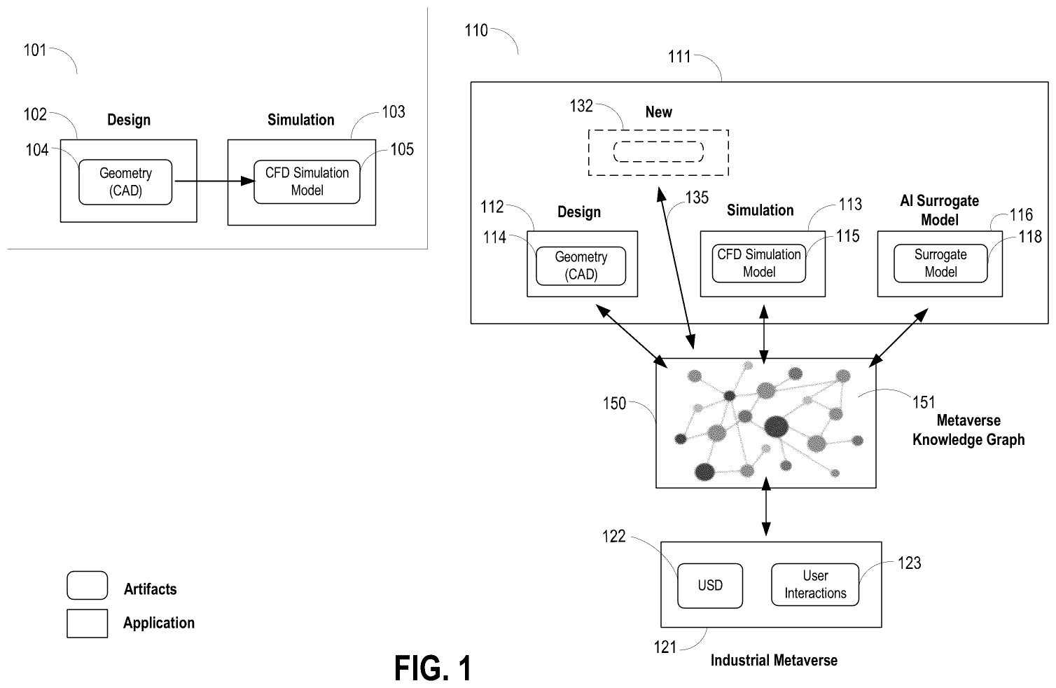

FIG. 1 illustrates a framework example for a virtual environment metaverse development using a metaverse knowledge graph in accordance with embodiments of this disclosure. A comparison is shown between a conventional application-to-application approach 101 and a proposed framework 110. Design pipelines 101 and 111 are shown having software applications relating to design, simulation and modeling, each application shown with a functional artifact (e.g., output, instance, or type of application). For the conventional approach 101, an example is presented in FIG. 1 consisting of a first platform that provides a design application 102 for generating (computer-aided design (CAD))-based geometry 104 related to an object under design, and a second platform that runs a simulation application 103 for generating a computational fluid dynamics (CFD) simulation model 105 corresponding to a particular design geometry 104 for the object under design. Such an arrangement lacks interoperability between the different platforms, which is the ability to seamlessly transfer information across the platforms. There is simply a one-to-one, unidirectional translation for each design instance. For example, there lacks any mechanism for interaction among different designs of design application 102 and different simulation models 105. As such, if any new simulation model 105 is called for, then a new design from design application 102 would have to be generated manually. Hence, this approach is not easily scalable,

In contrast, the proposed approach of a metaverse knowledge graph framework 110 provides the ability for seamless integration and interoperability across different platforms for engineering and design software applications. In an embodiment, a metaverse development pipeline 111 is used to develop a virtual environment of an industrial metaverse. Industrial metaverse application 121 is configured as a standalone software application that includes a universal scene description (USD) 3D framework 122 to virtually represent an industrial system design in a virtual environment. An artifact for user interactions 123 tracks information of user interactions with the industrial metaverse (virtual environment). In an embodiment, the industrial metaverse application 121 develops a virtual reality (VR) model that includes metaverse entities that are virtual objects, each corresponding with an object or entity in the software applications of various platforms of design pipeline 111. For example, industrial metaverse application 121 can acquire attributes from the metaverse knowledge graph 151 and build upon these attributes (e.g., virtual temperature, wind speed, pressure, etc.).

Elements from each metaverse pipeline application 112, 113, 116 can be rendered and displayed in the virtual environment of the industrial metaverse. For example, industrial metaverse application 121 receives design updates from each metaverse pipeline application 112, 113, 116 via the metaverse knowledge graph 151, and the geometry of the design is rendered to a user interface (e.g., graphical user interface) with simulation results visible (e.g., a fluid flow visualization as an overlay of vectors in a flow path).

Metaverse knowledge graph engine 150 generates and maintains metaverse knowledge graph 151, which allows exchanges of information across the software applications of the various platforms while developing the virtual environment and describes the semantics and the relationships between the metaverse entities of different platforms in the metaverse pipeline 111 including design application 112, simulation application 113 and an Artificial Intelligence (AI) surrogate model application 116 with surrogate model 118. Metaverse knowledge graph 151 bridges the gaps across metaverse development pipeline 111 platforms. For example, industrial metaverse application 121 is able to establish and discover the relationship among designs, simulation and surrogate models via the knowledge graph 151, whereby a new surrogate model can be inferred from a model in the metaverse knowledge graph 151. Metaverse knowledge graph 151 also standardizes the concepts that can be applied across the metaverse development pipeline 111, such as attributes of the applications, structure, relation and hierarchy among different metaverse development pipeline applications 111.

Metaverse knowledge graph 151 stores the information related to the engineering design or geometry 114 of the application as generated by design tool 112, any simulation models 115 for the design as generated using simulation tool 113, and any surrogate models 118 generated for the design by AI surrogate model tool 116. Metaverse knowledge graph 151 also stores information for scene description 112 (e.g., USD (Universal Scene Description) files) and user interactions in the metaverse as generated using the virtual environment tool 121.

In an embodiment, scalability with the metaverse knowledge graph approach 110 is a simple matter of adding a knowledge graph connection 135 to a new application 132 when being added to the metaverse development pipeline 111. In contrast, the conventional approach 101 lacks scalability.

The seamless integration of information in metaverse knowledge graph 151 enables synchronization across different platforms. The updates made by user interactions 123, or design changes via design tool 112 do not require a new design and development iteration. The updates can be seamlessly integrated into the design steps by running a few update queries to the metaverse knowledge graph 151. The changes can be transferred, and any user interaction and/or design changes can be assimilated automatically according to the new edits.

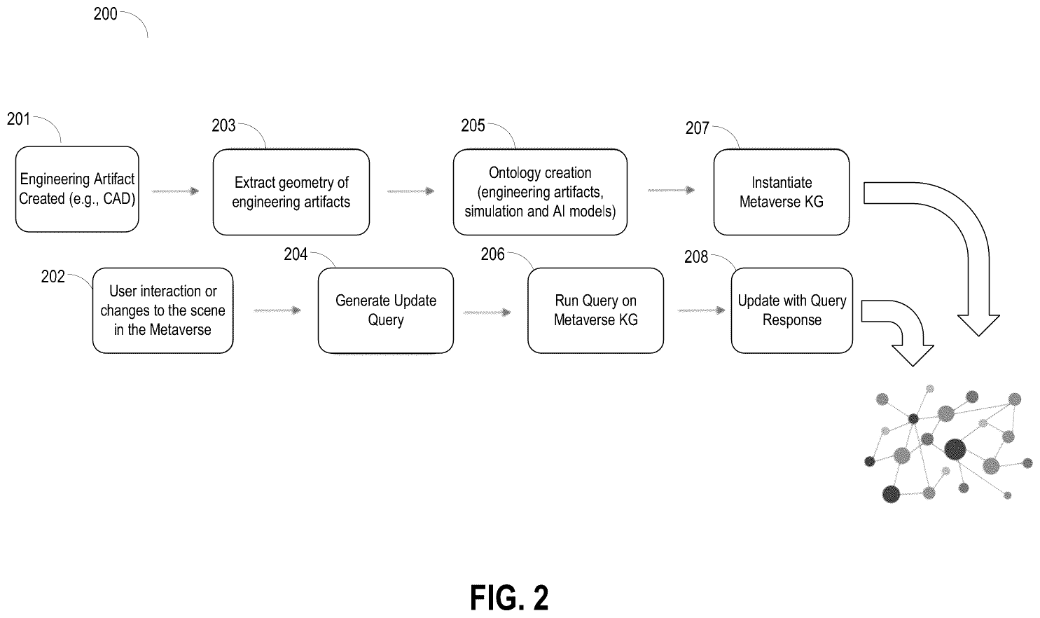

FIG. 2 illustrates an example of a process for data exchanges for the metaverse knowledge graph in accordance with embodiments of this disclosure. During engineering design activity, changes into the metaverse knowledge graph 151 can originate from multiple sources. Any changes in the models 118, design geometries 114, and virtual environment of the industrial metaverse can trigger a change and update query into the knowledge graph 151. Information is written to metaverse knowledge graph 151 as follows. Engineering artifacts are created (201) during geometry design (e.g., CAD) using the design tools 112. At 203, geometry 114 of the engineering artifacts is extracted. Knowledge graph engine 150 generates an ontology at 205 to describe the entities and relationships between the engineering artifacts, simulation models 115, and AI surrogate models 118. The ontology is based on pattern mining and association. As an example, multiple models may have the attribute of “wind speed”, in which case a label for “wind speed” is added to the ontology. At 207, the metaverse knowledge graph 151 is instantiated with the geometry 114, simulation models 115, surrogate models 118, user interactions 123, and scene description of the metaverse 122.

If any changes written to the metaverse knowledge graph 151 as described above impact other applications and artifacts, each impacted application and/or artifact will read the changes from the knowledge graph 151 and get updated. Knowledge graph 151 information is read as follows. User interactions 123 in industrial metaverse application 121 and/or changes to the metaverse scene description 122 made to knowledge graph 151 (in response to written changes as described above) are logged by the industrial metaverse application 121 at 202. An update query is automatically generated at 204 by each application in the metaverse development pipeline 111 in response to the changes made to the log. Metaverse knowledge graph engine 150 reads the current state of the knowledge graph 151, runs each update query at 206, and updates the connected metaverse platforms of pipeline 111 with a query response at 208. As an example of a platform application in pipeline 111 being updated, if the update involves changes in attributes or parameters such that the simulation application 113 automatically detects the need for a new simulation, the updated parameters are read by simulation application 113 from the query response and a new simulation is generated, which will then be written to the knowledge graph 151 for a new visualization of the simulation results. Likewise, surrogate models 118 update training data, parameters and structures to output new prediction results, to then be written to the metaverse knowledge graph 151. Updated attributes are processed by metaverse application 121 for a new visualization to the virtual environment of the virtual reality model, described by USD 112. Bidirectional communication links from the metaverse knowledge graph 151 to each application 112, 113, 116, 132, 121 enable the interoperability across dissimilar platforms for the read/write information exchanges shown in FIG. 2.

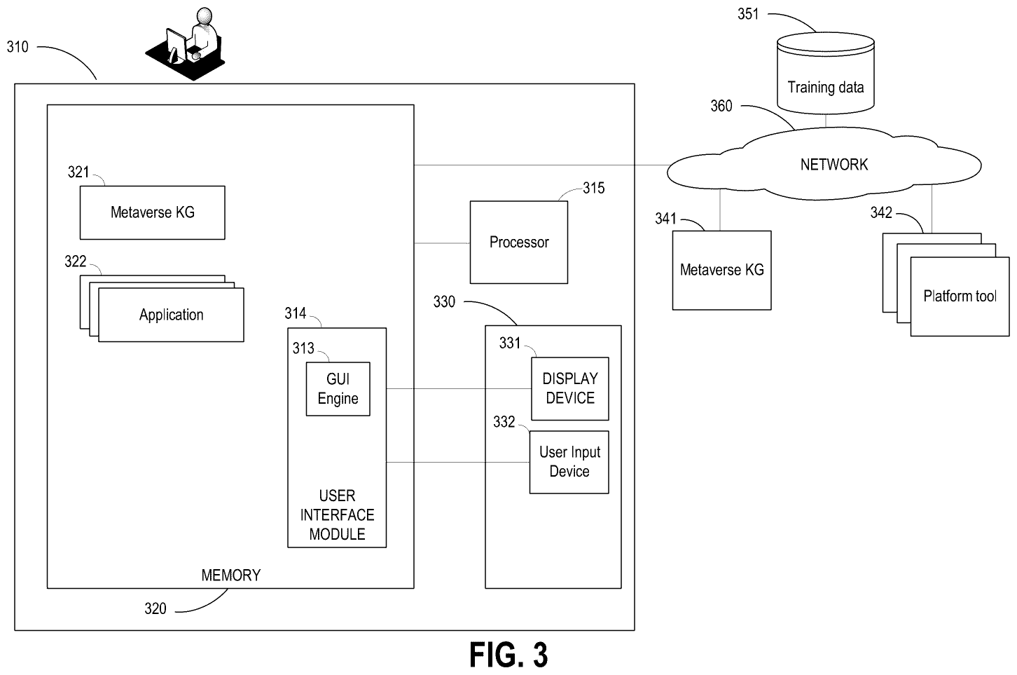

FIG. 3 shows an example of a computer environment within which embodiments of the disclosure may be implemented. A computing device 310 includes a processor 315 and memory 320 (e.g., a non-transitory computer readable media) on which is stored various computer applications, modules or executable programs. In an embodiment, memory 320 includes one or more of the following modules: a metaverse knowledge graph engine 321 and one or more application modules 322. Metaverse knowledge graph engine 321 executes algorithms for functionality corresponding to the above described metaverse knowledge graph engine 150. Application modules 322 executes algorithms for functionality corresponding to the various metaverse pipeline applications described for FIG. 1, such as design application 112, simulation application 113, AI surrogate model application 116 and industrial metaverse application 121.

As shown in FIG. 3, as an alternative computer implementation of metaverse knowledge graph engine 321, and application modules 322, one or more of a metaverse knowledge graph module 321 and application module 322 may be deployed as cloud-based or web-based operations, or as a divided operation shared by local modules 321, 322 and web-based modules 341, 342.

A network 360, such as a local area network (LAN), wide area network (WAN), or an internet based network, connects training data 351 to application modules 322 of computing device 310 and to cloud based application modules 342 related to training of AI simulation models.

User interface module 314 provides an interface between modules 321, 322 and user interface 330 devices, such as display device 331 and user input device 332. GUI engine 313 drives the display of an interactive user interface on display device 331, allowing a user to receive visualizations of analysis results and assisting user entry of learning objectives and domain constraints for metaverse knowledge graph module 321, 341, and application modules 322, 342.

Computer readable medium instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, may be implemented by computer readable medium instructions.

The program modules, applications, computer-executable instructions, code, or the like depicted in FIG. 3 as being stored in the system memory 320 are merely illustrative and not exhaustive and that processing described as being supported by any particular module may alternatively be distributed across multiple modules or performed by a different module. In addition, various program module(s), script(s), plug-in(s), Application Programming Interface(s) (API(s)), or any other suitable computer-executable code hosted locally on the computer system 310, remote network devices storing modules 341, 342 and/or hosted on other computing device(s) accessible via one or more of the network(s) 360, may be provided to support functionality provided by the program modules, applications, or computer-executable code and/or additional or alternate functionality. Further, functionality may be modularized differently such that processing described as being supported collectively by the collection of program modules depicted in FIG. 3 may be performed by a fewer or greater number of modules, or functionality described as being supported by any particular module may be supported, at least in part, by another module. In addition, program modules that support the functionality described herein may form part of one or more applications executable across any number of systems or devices in accordance with any suitable computing model such as, for example, a client-server model, a peer-to-peer model, and so forth. In addition, any of the functionality described as being supported by any of the program modules depicted in FIG. 3 may be implemented, at least partially, in hardware and/or firmware across any number of devices.

It should further be appreciated that the computer system 310 may include alternate and/or additional hardware, software, or firmware components beyond those described or depicted without departing from the scope of the disclosure. More particularly, it should be appreciated that software, firmware, or hardware components depicted as forming part of the computer system 310 are merely illustrative and that some components may not be present or additional components may be provided in various embodiments. While various illustrative program modules have been depicted and described as software modules stored in system memory 320, it should be appreciated that functionality described as being supported by the program modules may be enabled by any combination of hardware, software, and/or firmware. It should further be appreciated that each of the above-mentioned modules may, in various embodiments, represent a logical partitioning of supported functionality. This logical partitioning is depicted for ease of explanation of the functionality and may not be representative of the structure of software, hardware, and/or firmware for implementing the functionality. Accordingly, it should be appreciated that functionality described as being provided by a particular module may, in various embodiments, be provided at least in part by one or more other modules. Further, one or more depicted modules may not be present in certain embodiments, while in other embodiments, additional modules not depicted may be present and may support at least a portion of the described functionality and/or additional functionality. Moreover, while certain modules may be depicted and described as sub-modules of another module, in certain embodiments, such modules may be provided as independent modules or as sub-modules of other modules.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure. In addition, it should be appreciated that any operation, element, component, data, or the like described herein as being based on another operation, element, component, data, or the like can be additionally based on one or more other operations, elements, components, data, or the like. Accordingly, the phrase “based on,” or variants thereof, should be interpreted as “based at least in part on.”

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A computer based system for development of an industrial metaverse used in engineering by computer aided design, comprising:
a processor; and
a non-transitory memory having stored thereon modules executed by the processor, the modules comprising:
a metaverse development pipeline comprising a plurality of software applications of dissimilar platforms configured to generate information related to objects under design for an industrial facility;
an industrial metaverse application configured to generate a virtual environment representation of the objects under design and the industrial facility; and
a metaverse knowledge graph engine configured to:
instantiate and manage a metaverse knowledge graph describing semantics and relationships between the plurality of applications, and
exchange information across the plurality of software applications including updated information received any one of the plurality of software applications and the industrial metaverse application;
wherein the virtual environment is updated by the industrial metaverse application based on updates to the metaverse knowledge graph.

2. The system of claim 1, wherein the plurality of software applications includes at least one artificial intelligence (AI)-based surrogate model application configured to learn a surrogate model of the industrial system using machine learning.

3. The system of claim 2, wherein the metaverse knowledge graph stores information related to the engineering design or geometry as generated by the at least one design application, and any surrogate models for the design as generated by the at least one surrogate model application.

4. The system of claim 1, wherein the plurality of software applications includes at least one simulation application configured to generate a computational fluid dynamics (CFD) simulation model corresponding to a particular design geometry for the object under design.

5. The system of claim 1, wherein the industrial metaverse application comprises:
a universal scene description framework to virtually represent the object under design and related industrial system. facility and user interactions in the metaverse; and
a user interactions artifact for tracking information of user interactions with the industrial metaverse.

6. The system of claim 1, wherein the metaverse knowledge graph engine is configured to run update queries received from the plurality of software applications to synchronize metaverse entities of different platforms in the metaverse development pipeline.

7. The system of claim 1, wherein scalability of the metaverse knowledge graph is achieved by adding a bidirectional metaverse knowledge graph connection to a new software application being added to the metaverse development pipeline.

8. A computer-implemented method for developing a virtual environment of an industrial metaverse, comprising:
generating, by a design software application, engineering artifacts during geometry design of an industrial system;
extracting geometry of the engineering artifacts from the design software application;
extracting information from a simulation model or an AI surrogate model;
generating, by a knowledge graph engine, an ontology to describe the entities and relationships between the engineering artifacts, simulation model or artificial intelligence (AI) surrogate model; and
instantiating, by the knowledge graph engine, a metaverse knowledge graph with the engineering artifacts, simulation model or AI surrogate model information; and
generating, by an industrial metaverse application, a virtual environment representation of the object under design for an industrial system based on the metaverse knowledge graph;
wherein the virtual environment is updated by the industrial metaverse application based on updates to the metaverse knowledge graph.

9. The method of claim 8, further comprising:
logging user interactions or changes to the scene description;
generating an update query for the changes made to the log;
reading the current state of the knowledge graph; and
reading the update query and updating the models with a query response.

10. The method of claim 8, further comprising:
adding a bidirectional metaverse knowledge graph connection to a new software application being added to a metaverse development pipeline.
